(19) United States
(12) Patent Application Publication
(10) Pub. No.: US 2008/0259569 A1
(43) Pub. Date: Oct. 23, 2008

(54) THERMALLY ENHANCED BATTERY MODULE

(75) Inventor: Chia-Te Lin, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AMA PRECISION INC., Taipei (TW)

(21) Appl. No.: 12/105,286

(22) Filed: Apr. 18, 2008

(30) Foreign Application Priority Data
Apr. 20, 2007 (TW) 96113971

(51) Int. Cl. H05K 7/20

(52) U.S. Cl. 361/704

(57) ABSTRACT

A thermally enhanced battery module including a casing, at least a cell and a heat dissipation fin is provided. The casing has at least an opening, and the cell and the heat dissipation fin are both disposed in the casing. The cell has a contact surface, and the heat dissipation fin has an inner surface and an outer surface. Part of the inner surface contacts the contact surface of the cell. The outer surface has a plurality of notches and contacts the casing. At least one notch is exposed through the opening. The heat generated by the cell is capable of being dissipated by the heat dissipation fin and the opening in the invention to avoid overheating or decreasing the charging or discharging efficiency.

### CROSS-REFERENCE TO RELATED APPLICATION

This application claims the priority benefit of Taiwan application serial no. 96113971, filed on Apr. 20, 2007. The entirety the above-mentioned patent application is hereby incorporated by reference herein and made a part of specification.

### BACKGROUND OF THE INVENTION

1. Field of the Invention

The invention relates to a battery module and, more particularly to a thermally enhanced battery module.

2. Description of the Related Art

With the development of the science and technology, people become more dependent on electronic devices day by day. Portable electronic devices are loved by consumers for they are slim and light. To be used conveniently, a portable electronic device such as a notebook personal computer (PC) is usually equipped with a rechargeable battery for supplying power without an external power supply. Nowadays, a lithium ion battery whose electrolyte is lithium salt is commonly used as a rechargeable battery of a notebook PC.

The lithium salt is a liquid organic solvent, and it should be controlled in a safety temperature range to avoid explosion or decreasing the charging or discharging efficiency caused by overhearing in use. Therefore, a lithium ion battery usually consists of a plurality of cells covering the lithium salt and core to facilitate the control for the heat generated by the lithium salt in charging or discharging.

In the conventional skills, since the notebook computer has a low requirement for the generated power of the battery, the heat generated by the lithium ion battery in supplying power is not over high, which does not easily cause overheating. Therefore, a conventional lithium ion battery usually is not equipped with a heat dissipation system. However, since the functions of the notebook computer are diversified, power consumption is high, and the requirement for the generated power becomes higher day by day, the heat generated by the lithium ion battery becomes more and more. Therefore, the lithium ion battery should be redesigned in the aspect of the heat dissipation.

### BRIEF SUMMARY OF THE INVENTION

The invention provides a thermally enhanced battery module to allow heat generated by a cell of the thermally enhanced battery module to be dissipated via the heat dissipation fins and the openings, thereby avoiding the overheating of the cell or decreasing the charging or discharging efficiency.

The invention provides a thermally enhanced battery module including a casing, at least a cell and at least a heat dissipation fin. The casing has at least an opening, and the cell and the heat dissipation fin are provided in the casing. The cell has a contact surface, while the heat dissipation fin has an inner surface and an outer surface. the inner surface contacts the contact surface of the cell. The outer surface has a plurality of notches and contacts the casing to allow the opening to expose part of the notches.

In one embodiment of the invention, the thermally enhanced battery module includes a plurality of cells arranged as a first row of cells and a second row of cells. The first row of cells has a first contact surface, and the second row of cells has a second contact surface. A first portion of the inner surface is fitted with the first contact surface, and a second portion of the inner surface is fitted with the second contact surface.

In one embodiment, the contact area of the first row of cells and the inner surface is larger than the contact area of the second row of cells and the inner surface.

In one embodiment of the invention, the shape of the cells is column-shaped, while the shape of the first portion and the second portion is arc-shaped.

In one embodiment of the invention, the thermally enhanced battery module further includes a control circuit board. The control circuit board is provided in the casing and is electrically connected to the cells.

In one embodiment of the invention, the thermally enhanced battery module further includes at least a thermal conducting medium, and the cells are attached to the inner surface of the heat dissipation fins via the heat conducting medium.

In one embodiment of the invention, the heat conducting medium is thermal grease or a thermal conducting pad.

In one embodiment of the invention, the notch is jagged or wavy.

In one embodiment of the invention, the openings are rectangular and are arranged along the axial direction of the first row of cells and the second row of cells, and the long sides of the openings are about perpendicular to the extending direction of the notches.

In one embodiment of the invention, the shape of the heat dissipation fin is approximately L post-shaped, and the openings are located at one side or two adjacent sides of the casing correspondingly to the heat dissipation fin.

In one embodiment of the invention, the heat dissipation fin further has an anode processing layer formed at the inner surface and the outer surface.

The thermally enhanced battery module of the invention has a heat dissipation fin, and the casing has an opening. Therefore, the heat generated by the cells in supplying power is dissipated via the heat dissipation fin and the opening, which avoids the overheating of the cells and decreasing the charging or discharging efficiency.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing a thermally enhanced battery module according to the first embodiment of the invention.

FIG. 2 is an exploded diagram showing the thermally enhanced battery module in FIG. 1.

FIG. 3 is a schematic diagram showing a thermally enhanced battery module according to the second embodiment of the invention.

FIG. 4 is an exploded diagram showing the thermally enhanced battery module in FIG. 3.

FIG. 5 is a schematic diagram showing a thermally enhanced battery module according to the third embodiment of the invention.

FIG. 6 is an exploded diagram showing the thermally enhanced battery module in FIG. 5.

### DETAILED DESCRIPTION OF THE EMBODIMENTS

### First Embodiment

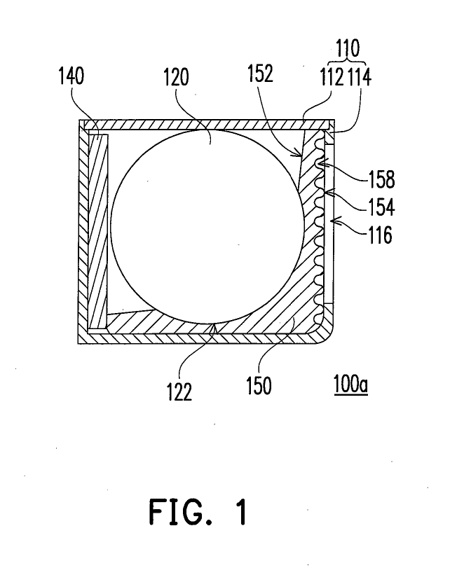

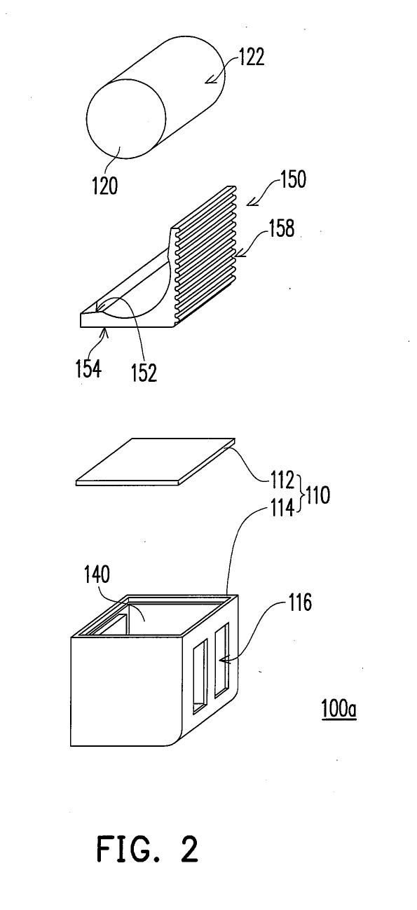

FIG. 1 is a schematic diagram showing the structure of a thermally enhanced battery module according to the first embodiment of the invention. FIG. 2 is an exploded diagram showing the thermally enhanced battery module in FIG. 1. The thermally enhanced battery module 110a includes a casing 110, a cell 120 and a heat dissipation fin 150. The casing 110 includes a cover 112 and a main body 114 and has one or more than one openings 116 located at one side of the main body 114. The material of the cover 112 and the main body 114 is insulator such as plastic. The cover 112 and the main body 114 cover the cell 120 and the heat dissipation fin 150, and the openings 116 at the main body 114 expose part of the heat dissipation fin 150.

In detail, the shape of the cell 120 is, for example, column-shaped and has a contact surface 122. The shape of the heat dissipation fin 150 is, for example, about L post-shaped and has an inner surface 152, an outer surface 154 and a plurality of notches 158 formed at one side of the outer surface 154. The shape of part of the inner surface 152 of the heat dissipation fin 150 is corresponding to the arc surface of the contact surface 122 of the cell 120 to allow the part of the inner surface 152 to be coupled with the contact surface 122 of the cell 120. The outer surface 154 of the heat dissipation fin 150 contacts the main body 114 of the casing 110 to allow the openings 116 of the main body 114 to expose at least one of the notches 158 correspondingly. The air outside the casing 110 flows between the notches 158 and the main body 114 through the openings 116.

The cell 120 contacts the inner surface 152 of the heat dissipation fin 150 via the contact surface 122 to conduct the heat to the heat dissipation fin 150. The air outside the casing 110 flows between the notches 158 and the main body 114 through the openings 116. Therefore, the heat generated by the cell 120 in supplying power is conducted to the heat dissipation fin 150 and is dissipated via the air flowing between the notches 158 and the main body 114. Thus, the temperature of the cell 120 is maintained in a safety temperature range.

In the first embodiment, the cell 120 is, for example, a standard lithium ion cell or a cell of a secondary battery which may be charged or discharged. The material of the heat dissipation fin 150 may consist of aluminum, copper or material with preferred heat conductivity. The notches 158 on the outer surface 154 of the heat dissipation fin 150 are, for example, jagged or wavy, and the extending direction of the notches 158 is parallel to the axial direction of the cell 120. In addition, the openings 116 at the main body 114 are, for example, rectangular and are arranged along the axial direction of the cell 120 sequentially. The long sides of the openings 116 are about perpendicular to the extending direction of the notches 158, which is not limited. The number of each component is not used to limit the invention. For example, the thermally enhanced battery module 100a also may be composed of a plurality of cells 120 connected in series and heat dissipation fins 150 with a corresponding quantity.

The thermally enhanced battery module 100a further may include a control circuit board 140 and a heat conducting medium (not shown). The control circuit board 140 is provided in the casing 110 and is electrically connected to the cell 120 to control the charging and discharging voltage of the cell 120. The heat conducting medium is attached to the inner surface 152 of the heat dissipation fin 150 to allow the cell 120 to contact the inner surface 152 of the heat dissipation fin 150 via the heat conducting medium. The heat conducting medium is, for example, thermal grease or a thermal conducting pad to allow the heat generated by the cell 120 in supplying power to be conducted to the heat dissipation fin 150 via the heat conducting medium quickly. In addition, the heat dissipation fin 150 further may have an anode processing layer (not shown) formed at the inner surface 152 and/or the outer surface 154. The anode processing layer is an insulator insulated from the electricity. The anode processing layer is, for example, alumina and allows the heat dissipation fin 150 to have the characteristic of “conducting heat instead of electricity”. The heat dissipation fin 150 is in the casing 110 and is not exposed directly, which avoids scalding the user.

### Second Embodiment

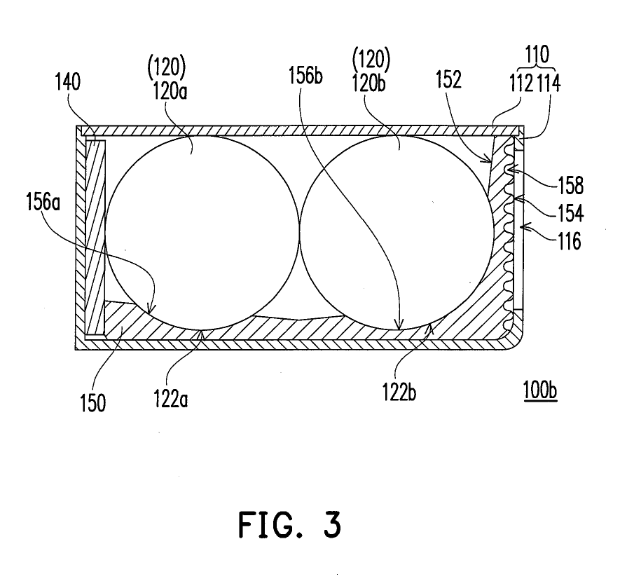

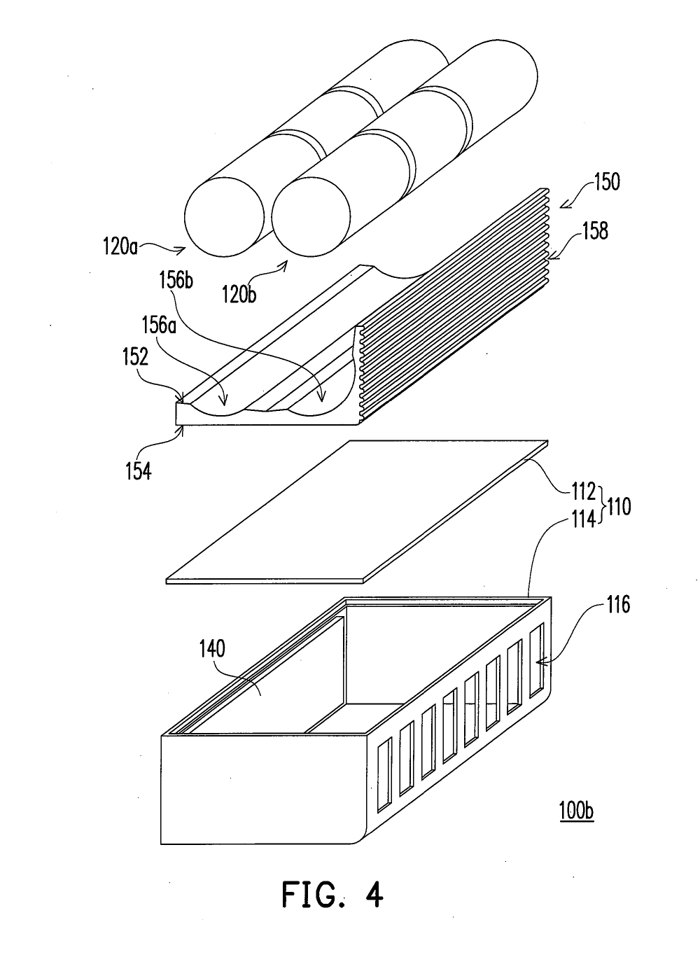

FIG. 3 is a schematic diagram showing a thermally enhanced battery module according to the second embodiment of the invention. FIG. 4 is an exploded diagram showing the thermally enhanced battery module in FIG. 3. The thermally enhanced battery module 110b includes a casing 110, a first row of cells 120a, a second row of cells 120b, a control circuit board 140 and a heat dissipation fin 150. The first row of cells 120a and the second row of cells 120b are, for example, formed by connecting a plurality of cells 120 in the first embodiment in series. Part of the inner surface 152 of the heat dissipation fin 150 contacts the surfaces of the first row of cells 120a and the second row of cells 120b. In addition, the structure, material and composing manner of the casing 110, the cells 120, the control circuit board 140 and the heat dissipation fin 150 are the same with that of the first embodiment, and therefore, they are not described for concise purpose.

In detail, part of the inner surface 152 of the heat dissipation fin 150 forms a first portion 156a and a second portion 156b. The shape of the first portion 156a is, for example, corresponding to that of the arc surface of the first contact surfaces 122a of the first row of cells 120a. Thus, the first contact surfaces 122a of the first row of cells 120a are coupled with the first portion 156a. Similarly, the shape of the second portion 156b is, for example, corresponding to that of the arc surface of the second contact surfaces 122b of the second row of cells 120b. Thus, the contact surfaces 122b of the second row of cells 120b are coupled with the second portion 156b. Furthermore, the control circuit board 140 is, for example, electrically connected to the first row of cells 120a and the second row of cells 120b to control the charging and discharging voltage of the first row of cells 120a and the second row of cells 120b. The first row of cells 120a is, for example, provided between the second row of cells 120b and the control circuit board 140.

Similarly, the first row of cells 120a and the second row of cells 120b may conduct the heat to the heat dissipation fin 150 by contacting the inner surface 152 of the heat dissipation fin 150, and the air outside the casing 110 flows between the notches 158 and the main body 114 through the openings 116. Therefore, the heat generated by the first row of cells 120a and the second row of cells 120b in supplying power may be conducted to the heat dissipation fin 150. Therefore, the temperature of the first row of cells 120a and the second row of cells 120b is maintained in a safety temperature range via dissipating the heat by the air flowing between the notches 158 and the main body 114.

### Third Embodiment

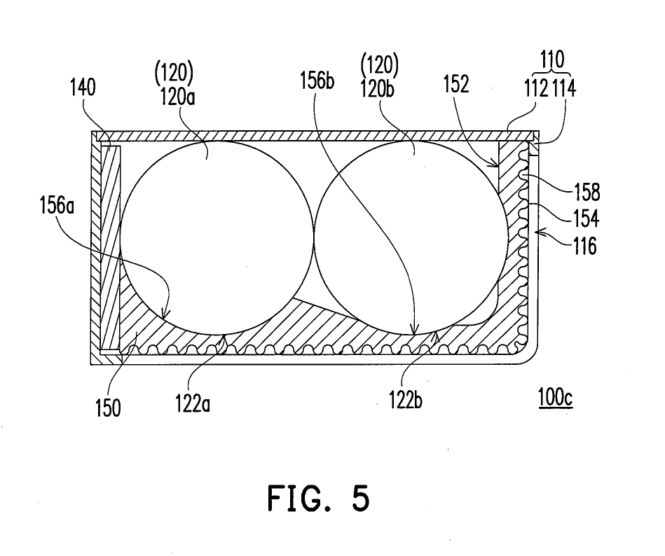

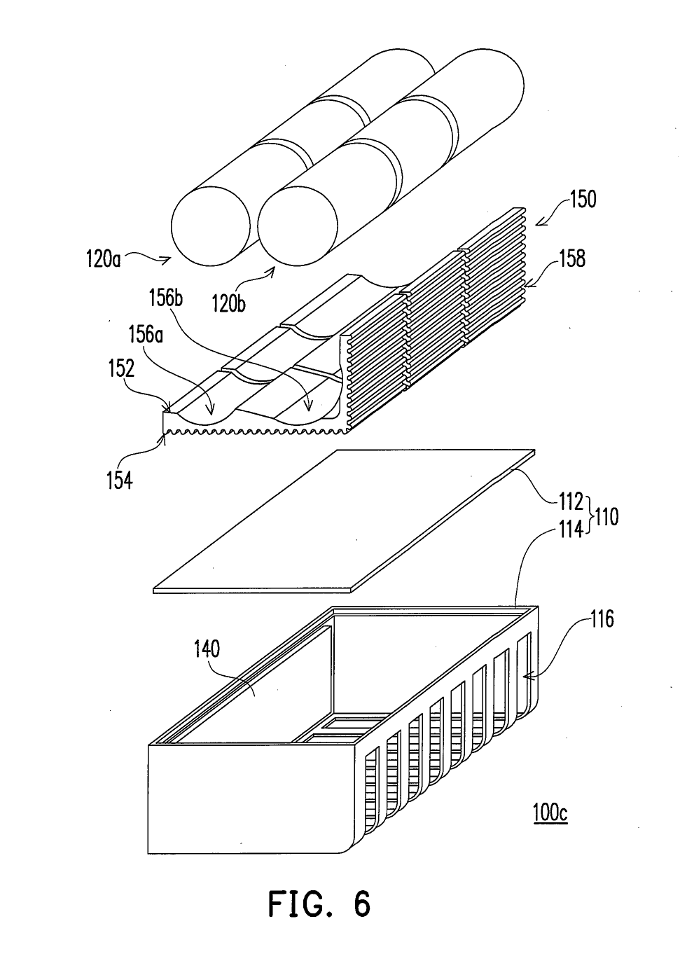

FIG. 5 is a schematic diagram showing the structure of a thermally enhanced battery module according to the third embodiment of the invention. FIG. 6 is an exploded diagram showing the thermally enhanced battery module in FIG. 5. The structure of the thermally enhanced battery module 110c of the third embodiment is about same with that of the thermally enhanced battery module 100b of the second embodiment. The difference between them is that the number of heat dissipation fin 150 and the section shape thereof, the number of the notches 158 of the heat dissipation fin 150 and the shape of the openings 116 at the main body 114 in the thermally enhanced battery module 110c are different from those of the thermally enhanced battery module 100b in the second embodiment.

In the third embodiment, the thermally enhanced battery module 100b includes three heat dissipation fins 150 corresponding to the cells 120 of the first row of cells 120a and the second row of cells 120b. The notches 158 are formed at the two adjacent sides of the outer surface 154 of the heat dissipation fin 150. The openings 116 extends at the two adjacent sides of the main body 114 and are near to the adjacent sides of the outer surface 154 of the heat dissipation fin 150 to expose the notches 158 correspondingly. In addition, the section shape of the heat dissipation fins 150, the size and the position of the openings 116 are, for example designed in compliance with optimization principle according to the heat generated by the cells 120. When the heat generated by the first row of cells 120a is more than the heat generated by the second row of cells 120b, the contact area of the first row of cells 120a and the inner surface 152 of the heat dissipation fin 150 may be designed to be larger than the contact area of the second row of cells 120b and the inner surface 152 of heat dissipation fin 150. Thus, the heat dissipation efficiency of the first row of cells 120a is increased, and then the temperature of the first row of cells 120a is about same with that of the second row of cells 120b in supplying power.

The above embodiment is not used to limit the invention. For example, the first row of cells 120a and the second row of cells 120b are not limited to be composed of three cells 120, and they are also may be composed of cells 120 with a different quantity which are connected in series. The number of the heat dissipation fins 150 is also not limited to be three. Furthermore, the total number of the cells 120 of the thermally enhanced battery modules 100b and 100c are not limited to be six, and it may be less than six or more than six. At that moment, the thermally enhanced battery modules 100b and 100c also may be composed of three rows of cells or more rows of cells, and the inner surface 152 of the heat dissipation fin 150 also may form third coupling portion or more coupling portions to contact the cells 120. Similarly, the notches 158 formed on the outer surface 154 of the heat dissipation fins 150 are not limited to be wavy, and they may be jagged.

In addition, the long sides of the notches 158 also may be perpendicular to the axial direction of the first row of cells 120a and the second row of cells 120b and extend at one side or two adjacent sides of the outer surface 154 of the heat dissipation fin 150. At that moment, the openings 116 at the main body 114 are, for example, located at one side or two adjacent sides correspondingly to the notches 158 of the heat dissipation fins 150 and arranged along the axial direction of the first row of cells 120a and the second row of cells 120b in sequence.

To sum up, since the thermally enhanced battery module of the invention has a heat dissipation fin, and the casing thereof has an opening. Therefore, the heat generated by the cells in supplying power may be dissipated via the heat dissipation fin and the openings to avoid overheating of the cells and decreasing the charging discharging efficiency.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A thermally enhanced battery module comprising:
a casing having at least an opening;
at least a cell provided in the casing and having a contact surface; and
at least a heat dissipation fin provided in the casing and having an inner surface and an outer surface, the inner surface contacting the contact surface of the cell, and the outer surface has a plurality of notches and contacting the casing to allow the opening to expose part of the notches.

2. The thermally enhanced battery module according to claim 1, wherein a plurality of cells are arranged as a first row of cells having a first contact surface and a second row of cells having a second contact surface, the inner surface has a first portion and a second portion, respectively, the first portion is fitted with part of the first contact surface, and the second portion of the inner surface is fitted with part of the second contact surface.

3. The thermally enhanced battery module according to claim 2, wherein the contact area of the first row of cells and the inner surface is larger than the contact area of the second row of cells and the inner surface.

4. The thermally enhanced battery module according to claim 2, wherein the shape of the cells are column-shaped, and the shape of the first portion and the second portion is are-shaped.

5. The thermally enhanced battery module according to claim 1, further comprising a control circuit board provided in the casing and electrically connected to the cell.

6. The thermally enhanced battery module according to claim 1, further comprising at least a heat conducting medium via which the cell is attached to the inner surface of the heat dissipation fin.

7. The thermally enhanced battery module according to claim 6, wherein the heat conducting medium is thermal grease or a heat conducting pad.

8. The thermally enhanced battery module according to claim 1, wherein the notches are jagged or wavy.

9. The thermally enhanced battery module according to claim 1, wherein the openings are rectangular and are arranged along the axial direction of the cell, and the long sides of the openings are about perpendicular to the extending direction of the notches.

10. The thermally enhanced battery module according to claim 1, wherein the heat dissipation fin is about L post-shaped, and the openings are located at one side or two adjacent sides of the casing correspondingly to the heat dissipation fin.

11. The thermally enhanced battery module according to claim 1, wherein the heat dissipation fin further has an anode processing layer formed at the inner surface and the outer surface.
